(19) United States
(12) Patent Application Publication
(10) Pub. No.: US 2025/0227947 A1
(43) Pub. Date: Jul. 10, 2025

(54) NITRIDE-BASED SEMICONDUCTOR DEVICE AND METHOD FOR MANUFACTURING THE SAME

(71) Applicant: INNOSCIENCE (SUZHOU) SEMICONDUCTOR CO., LTD., Jiangsu (CN)

(72) Inventors: Peng-Yi WU, Jiangsu (CN); Chuangang LI, Jiangsu (CN); Yuanyu WU, Jiangsu (CN)

(73) Assignee: INNOSCIENCE (SUZHOU) SEMICONDUCTOR CO., LTD., Jiangsu (CN)

(21) Appl. No.: 18/852,507

(22) PCT Filed: Mar. 30, 2022
(86) PCT No.: PCT/CN2022/083901

§ 371 Date: Sep. 30, 2024

(51) Int. Cl. H10D 30/47; H10D 30/01; H10D 62/10; H10D 62/53; H10D 62/60; H10D 62/824

(52) U.S. Cl. CPC H10D 30/475; H10D 30/015; H10D 62/102; H10D 62/53; H10D 62/60; H10D 62/824

(57) ABSTRACT

A nitride-based semiconductor device includes III-V nitride-based buffer layer, a first III-V nitride-based semiconductor layer, and second III-V nitride-based semiconductor layer. The III-V nitride-based buffer layer is disposed over a substrate to form a first interface with the substrate. The III-V nitride-based buffer layer has a plurality of first dislocation lines extending from the first interface to a top surface of the III-V nitride-based buffer layer. The first III-V nitride-based semiconductor layer is disposed over the III-V nitride-based buffer layer to form a second interface with the top surface of the III-V nitride-based buffer layer. The first III-V nitride-based semiconductor layer has a plurality of second dislocation lines. Each of the second dislocation lines connects two of the first dislocation lines. The second III-V nitride-based semiconductor layer is disposed over the first III-V nitride-based semiconductor layer.

### FIELD OF THE DISCLOSURE

The present disclosure generally relates to a nitride-based semiconductor device. More specifically, the present disclosure relates to a nitride-based semiconductor device having a varied V/III ratio to modify dislocation trend in its structure.

### BACKGROUND OF THE DISCLOSURE

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY OF THE DISCLOSURE

In accordance with one aspect of the present disclosure, a nitride-based semiconductor device is provided. The nitride-based semiconductor device includes III-V nitride-based buffer layer, a first III-V nitride-based semiconductor layer, and second III-V nitride-based semiconductor layer. The III-V nitride-based buffer layer is disposed over a substrate to form a first interface with the substrate. The III-V nitride-based buffer layer has a plurality of first dislocation lines extending from the first interface to a top surface of the III-V nitride-based buffer layer. The first III-V nitride-based semiconductor layer is disposed over the III-V nitride-based buffer layer to form a second interface with the top surface of the III-V nitride-based buffer layer. The first III-V nitride-based semiconductor layer has a plurality of second dislocation lines and third dislocation lines. Each of the second dislocation lines connects two of the first dislocation lines, and each of the third dislocation lines continuously extends from corresponding one of the first dislocation lines to a top surface of the first III-V nitride-based semiconductor layer. The second III-V nitride-based semiconductor layer is disposed over the first III-V nitride-based semiconductor layer to form a third interface with the top surface of the first III-V nitride-based semiconductor layer.

In accordance with one aspect of the present disclosure, a method

for manufacturing a nitride-based semiconductor device is provided. The method includes steps as follows. A III-V nitride-based buffer layer is formed over a substrate with a plurality of first dislocation lines extending in the III-V nitride-based buffer layer. A first III-V nitride-based semiconductor layer is formed over the III-V nitride-based buffer layer by applying a first V/III ratio during growth of the first III-V nitride-based semiconductor layer, such that a plurality of second dislocation lines are formed in the first III-V nitride-based semiconductor layer with each of the second dislocation lines connected two of the first dislocation lines. A second III-V nitride-based semiconductor layer is formed over the first III-V nitride-based semiconductor layer by applying a second V/III ratio during growth of the second III-V nitride-based semiconductor layer, in which the first V/III ratio is lower than the second V/III ratio.

In accordance with one aspect of the present disclosure, a nitride-based semiconductor device is provided. The nitride-based semiconductor device includes a III-V nitride-based buffer layer, a first III-V nitride-based semiconductor layer, and a second III-V nitride-based semiconductor layer. The III-V nitride-based buffer layer is disposed over a substrate to form a first interface with the substrate. The first III-V nitride-based semiconductor layer is disposed over the III-V nitride-based buffer layer and makes contact with the III-V nitride-based buffer layer. A first dislocation line extends from an interface between the substrate and the III-V nitride-based buffer layer to the first III-V nitride-based semiconductor layer and then back to the interface between the substrate and the III-V nitride-based buffer layer. A second dislocation line extends from the interface between the substrate and the III-V nitride-based buffer layer to a top surface of the first III-V nitride-based semiconductor layer. A second III-V nitride-based semiconductor layer is disposed over the first III-V nitride-based semiconductor layer to form an interface with the top surface of the first III-V nitride-based semiconductor layer.

By the above configuration, the III-V nitride-based semiconductor layer can be formed with the sub-III-V nitride-based layers with different V/III ratios. The different V/III ratios can let dislocation line turn to extend laterally, so the dislocation line can become reverse U-shaped so to reduce dislocation density.

### BRIEF DESCRIPTION OF THE DRAWINGS:

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1 is a vertical view of a nitride-based semiconductor device according to some embodiments of the present disclosure;

FIG. 2 is a cross-section view schematically showing a partial structure of a semiconductor device according to a comparative embodiment;

FIG. 3A and FIG. 3B show different stages of a method for manufacturing a nitride-based semiconductor device according to some embodiments of the present disclosure.

FIG. 4 is a vertical view of a nitride-based semiconductor device according to some embodiments of the present disclosure;

FIG. 5 is a vertical view of a nitride-based semiconductor device according to some embodiments of the present disclosure; and

FIG. 6 is a vertical view of a nitride-based semiconductor device according to some embodiments of the present disclosure.

### DETAILED DESCRIPTION:

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

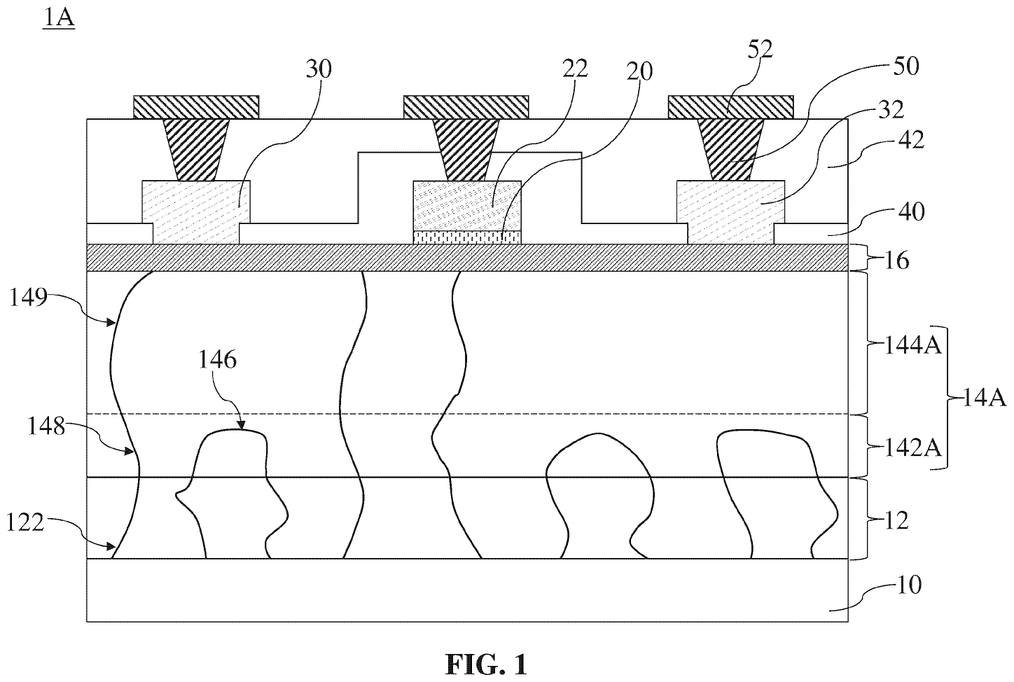

FIG. 1A is a vertical view of a nitride-based semiconductor device 1A according to some embodiments of the present disclosure. The nitride-based semiconductor device 1A includes a substrate 10, a buffer layer 12, nitride-based semiconductor layers 14A, 16, a doped nitride-based semiconductor layer 20, a gate electrode 22, electrodes 30 and 32, passivation layers 40 and 42, contact vias 50, and a patterned conductive layer 52.

The substrate 10 may be a semiconductor substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

The buffer layer 12 can be disposed on/over/above the substrate 10. The buffer layer 12 can be disposed between the substrate 10 and the nitride-based semiconductor layer 14A. The buffer layer 12 can be configured to reduce lattice and thermal mismatches between the substrate 10 and the nitride-based semiconductor layer 14A, thereby curing defects due to the mismatches/difference. The buffer layer 12 may include a III-V compound. The III-V compound can include, for example but are not limited to, aluminum, gallium, indium, nitrogen, or combinations thereof. Accordingly, the exemplary materials of the buffer layer can further include, for example but are not limited to, GaN, AlN, AlGaN, InAlGaN, or combinations thereof. In some embodiments, the buffer layer 12 can be called a III-V nitride-based buffer layer. The III-V nitride-based buffer layer forms an interface with the substrate 10.

In some embodiments, the semiconductor device 1A may further include a nucleation layer (not shown). The nucleation layer may be formed between the substrate 10 and the buffer layer 12. The nucleation layer can be configured to provide a transition to accommodate a mismatch/difference between the substrate 10 and a III-nitride layer of the buffer layer 12. The exemplary material of the nucleation layer can include, for example but is not limited to AIN or any of its alloys.

The nitride-based semiconductor layer 14A can be disposed on/over/above the buffer layer 12. The nitride-based semiconductor layer 14A can make contact with the buffer layer 12. The nitride-based semiconductor layer 14A can form an interface with a top surface of the buffer layer 12. The nitride-based semiconductor layer 16 can be disposed on/over/above the nitride-based semiconductor layer 14A. The nitride-based semiconductor layer 16 can make contact with the nitride-based semiconductor layer 14A. The nitride-based semiconductor layer 16 can form an interface with a top surface of the nitride-based semiconductor layer 14A.

The exemplary materials of the nitride-based semiconductor layer

14A can include, for example but are not limited to, nitrides or group III-V compounds, such as GaN, AlN, InN, InxAlyGa_{(1-x-y)}N where x+y≤1, AlyGa(_{1-y})N where y≤1. The exemplary materials of the nitride-based semiconductor layer 16 can include, for example but are not limited to, nitrides or group III-V compounds, such as GaN, AlN, InN, InxAlyGa(_{1-x-y})N where x+y≤1, AlyGa(_{1-y})N where y≤1.

The exemplary materials of the nitride-based semiconductor layers 14A and 16 are selected such that the nitride-based semiconductor layer 16 has a bandgap (i.e., forbidden band width) greater/higher than a bandgap of the nitride-based semiconductor layer 14A, which causes electron affinities thereof different from each other and forms a heterojunction therebetween. For example, when the nitride-based semiconductor layer 14A is an undoped GaN layer having a bandgap of approximately 3.4 eV, the nitride-based semiconductor layer 16 can be selected as an AlGaN layer having bandgap of approximately 4.0 eV. As such, the nitride-based semiconductor layers 14A and 16 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction.

Accordingly, the semiconductor device 1A is available to include at least one GaN-based high-electron-mobility transistor (HEMT).

In some embodiment, the nitride-based semiconductor layer 14A has a bottom portion 142A and a top portion 144A over the bottom portion. The bottom portion 142A is connected to the top portion 144A. In some embodiments, the bottom portion 142A and the top portion 144A of the nitride-based semiconductor layer 14A are merged with each other so no visible interface is formed therebetween. In some embodiments, the bottom portion 142A and the top portion 144A of the nitride-based semiconductor layer 14A are connected with each other with a visible interface formed therebetween.

The nitride-based semiconductor layer 14A may have different qualities between top and bottom potions 142A and 144A. The reason is that the bottom portion 142A may have a dislocation density higher than that of the top portion 144A. The bottom portion 142A can serve as a dislocation transition layer for accommodating most of dislocations and terminate there, so as to avoid them vertically extending upward. As such, the top portion 144A can serve as a channel layer since its dislocation density is less than that of the bottom portion 142A. In the present disclosure, the nitride-based semiconductor layer 14A is formed by using more than one recipe of V/III ratio to achieve the for accommodating most of dislocations.

In this regard, once a nitride-based semiconductor layer formed on a buffer layer cannot accommodate most of dislocations and let terminate there, it will result in high dislocation density adjacent with a channel layer. Such the channel layer may have defeats inside so have performance worsen thereof.

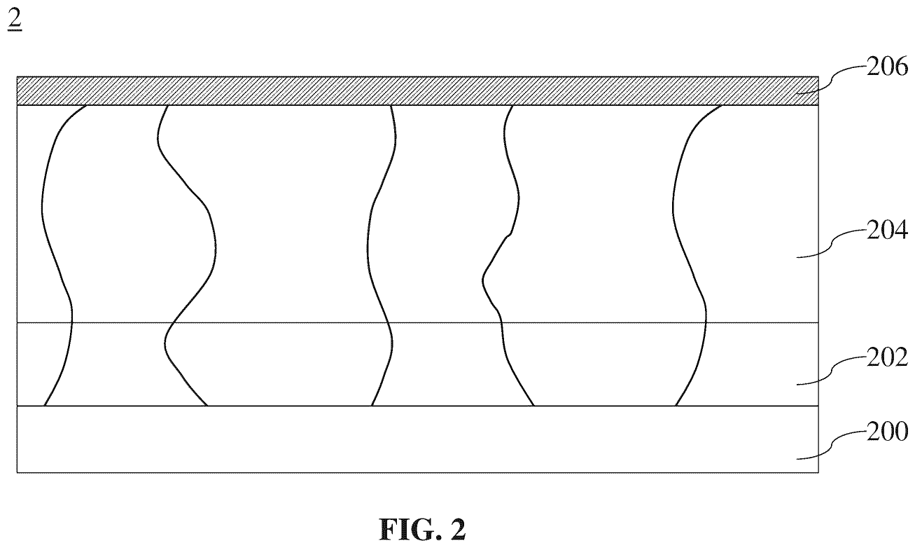

For example, FIG. 2 is a cross-section view schematically showing a partial structure of a semiconductor device 2 according to a comparative embodiment. The semiconductor device 2 includes a buffer layer 202 on a substrate 200, a nitride-based semiconductor layer 204 on the buffer layer 202, and a nitride-based semiconductor layer 206 on the nitride-based semiconductor layer 204.

During the growth of the buffer layer 202, dislocation lines may be generated with the growth and extend upward. At the stage of the growth of the nitride-based semiconductor layer 204, the dislocation lines continuously pass through the nitride-based semiconductor layer 204. The dislocation lines can get adjacent with the nitride-based semiconductor layer 206 and enter the same. The high dislocation density will affect the film quality of the nitride-based semiconductor layers 204 and 206, which is an undesired status.

Referring to FIG. 1 again, the buffer layer 12 has a plurality of dislocation lines 122 passing through the buffer layer 12. The dislocation lines 122 can extend from the interface between the substrate 10 and the buffer layer 12 to a top surface of the buffer layer 12.

As afore-mentioned, the nitride-based semiconductor layer 14 is formed by using more than one recipe of V/III ratio. In some embodiments, the bottom portion 142A and the top portion 144A of the nitride-based semiconductor layer 14A are formed by applying different V/III ratios. In some embodiments, the V/III ratio of the bottom portion 142A is lower than the V/III ratio of the top portion 144A.

In some embodiments, the V/III ratio includes V/III flux ratio during epitaxial growth. The difference at the V/III ratios of the bottom portion 142A and the top portion 144A of the nitride-based semiconductor layer 14 will result in different epitaxial characters.

In this regard, when a layer is formed by using epitaxial growth in a low V/III ratio, lateral growth energy is greater than longitudinal growth energy, which means dislocations lines generated in a low V/III ratio epitaxial layer will have lateral growth trend. When a layer is formed by using epitaxial growth in a high V/III ratio, longitudinal growth energy is greater than lateral growth energy, which means dislocations lines generated in a low V/III ratio epitaxial layer will have longitudinal growth trend.

Therefore, as the bottom portion 142A of the nitride-based semiconductor layer 14A is formed on the buffer layer 12 with the low V/III ratio applied, the bottom portion 142A can guide the dislocation lines 122 of the buffer layer 12 into lateral growth trend. As such, at least some of the dislocation lines 122 of the buffer layer 12 can laterally grow to get closer with each other so they will connect with each other eventually, which are labeled as dislocation lines 146 in the bottom portion 142A of the nitride-based semiconductor layer 14A. More specifically, each of the dislocation lines 146 can connect two of the dislocation lines 122 adjacent with each other.

The dislocation lines 146 can have various profiles. In some embodiments, each of the dislocation lines 146 can turn around in the bottom portion 142A of the nitride-based semiconductor layer 14A. In some embodiments, each of the dislocation lines 146 is reverse U-shaped. Accordingly, none of the dislocation lines 146 penetrates the III-V nitride-based semiconductor layer 14A. In some embodiments, the dislocation line 122 in combination with the dislocation line 146 can extend from the interface between the substrate 10 and the buffer layer 12 to the III-V nitride-based semiconductor layer 14A and then back to the interface between the substrate 10 and the buffer layer 12.

Another group of the dislocation lines 122 of the buffer layer 12 keeps longitudinal growth energy so extends longitudinally, which are labeled as dislocation lines 148 in the bottom portion 142A of the nitride-based semiconductor layer 14A. Each of the dislocation lines 148 can continuously extend from corresponding one of the dislocation lines 122 to pass through the bottom portion 142A of the nitride-based semiconductor layer 14A.

Since the dislocation lines 146 can remain in the in the bottom portion 142A, the number of dislocation lines over the bottom portion 142A decreases, resulting in the dislocation concentration over the bottom portion 142A reduced. More specifically, as the top portion 144A of the nitride-based semiconductor layer 14A continues to grow from the bottom portion 142A of the nitride-based semiconductor layer 14A with the high V/III ratio applied, only the dislocation lines 148 can get into the top portion 144A, so the dislocation concentration of the top portion 144A reduces. In other words, a dislocation density of the bottom portion 142A is greater than a dislocation density of the top portion 144A.

The dislocation lines 149 are labeled in the top portion 144A of the nitride-based semiconductor layer 14A. The dislocation lines 149 can continuously extend from corresponding one of the dislocation lines 148 to the top surface of the III-V nitride-based semiconductor layer 14A to reach the interface between the III-V nitride-based semiconductor layers 14A and 16. In some embodiments, since the dislocation lines 149 can keep longitudinal growth energy, so each of the dislocation lines 146 is more curved than the dislocation lines 149. Similarly, each of the dislocation lines 146 is more curved than the dislocation lines 122.

In some embodiments, the low V/III ratio is equal to or less than about 200. In some embodiments, the low V/III ratio is in a range from about 20 to about 200. In some embodiments, the high V/III ratio is equal to or greater than about 500. In some embodiments, the high V/III ratio is in a range from about 500 to about 7000.

In the present embodiments, the V/III ratio of the III-V nitride-based semiconductor layer 14A from the bottom portion 142A to the top portion 144A is gradually increasing. For example, the V/III ratio of the III-V nitride-based semiconductor layer 14A may vary along the thickness direction. In some embodiments, the V/III ratio of the III-V nitride-based semiconductor layer 14A from the bottom portion 124 to the top portion 144A is in a range from about 200 to about 500.

In some embodiments, the different V/III ratios of the bottom portion 142A and the top portion 144A of the III-V nitride-based semiconductor layer 14A may result in different concentrations of a group III element thereof. For example, the bottom portion 142A and the top portion 144A of the III-V nitride-based semiconductor layer 14A may have different aluminum concentrations. In some embodiments, the aluminum concentration of the III-V nitride-based semiconductor layer 14A may decrease in the bottom portion 142A. The different aluminum concentrations of the bottom portion 142A and the top portion 144A of the III-V nitride-based semiconductor layer 14A can be made to adapt the character requirements of the channel layer. In some embodiments, such the configuration can lead element concentration into a compatible condition for growing a channel layer.

By the configuration above, the film quality is improved due to the dislocation density adjacent with the channel layer reduced. Accordingly, the performance of the HEMT to be formed over the channel layer can get enhanced.

In this regard, a nitride-based transistor can be disposed over the nitride-based semiconductor layers 14A and 16. The nitride-based transistor can be constituted by the doped nitride-based semiconductor layer 20, the gate electrode 22, and the electrodes 30 and 32.

The doped nitride-based semiconductor layer 20 and the gate electrode 22 are stacked on the nitride-based semiconductor layer 16. The doped nitride-based semiconductor layer 20 is between the nitride-based semiconductor layer 16 and the gate electrode 22.

The semiconductor device 1A can be designed as being an enhancement mode device, which is in a normally-off state when the gate electrode 22 is at approximately zero bias. Specifically, the doped nitride-based semiconductor layer 20 creates a p-n junction with the nitride-based semiconductor layer 14A to deplete the 2DEG region, such that a zone of the 2DEG region corresponding to a position below the gate electrode 22 has different characteristics (e.g., different electron concentrations) than the rest of the 2DEG region and thus is blocked. Due to such mechanism, the semiconductor device 1A has a normally-off characteristic. In other words, when no voltage is applied to the gate electrode 22 or a voltage applied to the gate electrode 22 is less than a threshold voltage (i.e., a minimum voltage required to form an inversion layer below the gate electrode 22), the zone of the 2DEG region below the gate electrode 22 is kept blocked, and thus no current flows therethrough. Moreover, by providing the doped nitride-based semiconductor layer 20, gate leakage current is reduced and an increase in the threshold voltage during the off-state is achieved.

In some embodiments, the doped nitride-based semiconductor layer 20 can be omitted, such that the semiconductor device 1A is a depletion-mode device, which means the semiconductor device 1A in a normally-on state at zero gate-source voltage.

The exemplary materials of the doped nitride-based semiconductor layer 20 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd. In some embodiments, the nitride-based semiconductor layer 14A includes undoped GaN and the nitride-based semiconductor layer 16 includes AlGaN, and the doped nitride-based semiconductor layer 20 is a p-type GaN layer which can bend the underlying band structure upwards and to deplete the corresponding zone of the 2DEG region, so as to place the semiconductor device 1A into an off-state condition.

In some embodiments, the gate electrode 22 may include metals or metal compounds. The exemplary materials of the metals or metal compounds can include, for example but are not limited to, W, Au, Pd, Ti, Ta, Co, Ni, Pt, Mo, TiN, TaN, metal alloys thereof, or other metallic compounds. In some embodiments, the exemplary materials of the gate electrode 22 may include, for example but are not limited to, nitrides, oxides, silicides, doped semiconductors, or combinations thereof. In some embodiments, the optional dielectric layer can be formed by a single layer or more layers of dielectric materials. The exemplary dielectric materials can include, for example but are not limited to, one or more oxide layers, a SiOx layer, a SiNx layer, a high-k dielectric material (e.g., HfO₂, Al₂O₃, TiO₂, HfZrO, Ta₂O₃, HfSiO₄, ZrO₂, ZrSiO₂, etc), or combinations thereof.

The passivation layer 40 is disposed over the nitride-based semiconductor layer 16. The passivation layer 40 covers the gate structure 124 for a protection purpose. The exemplary materials of the passivation layer 40 can include, for example but are not limited to, SiNx, SiOx, SiON, SiC, SiBN, SiCBN, oxides, nitrides, or combinations thereof. In some embodiments, the passivation layer 40 is a multi-layered structure, such as a composite dielectric layer of Al₂O₃/SiN, Al₂O₃/SiO₂, AlN/SiN, AlN/SiO₂, or combinations thereof.

The electrodes 30 and 32 are disposed on the nitride-based semiconductor layer 16. The electrodes 30 and 32 are located at two opposite sides of the gate electrode 22 (i.e., the gate electrode 22 is located between the electrodes 30 and 32). The gate electrode 22 and the electrodes 30 and 32 can collectively act as a GaN-based HEMT with the 2DEG region.

The electrodes 30 and 32 have bottom portions penetrating the passivation layer 40 to form interfaces with the nitride-based semiconductor layer 16. The electrodes 30 and 32 have top portions wider than the bottom portions thereof. The top portions of the electrodes 30 and 32 extend over portions of the passivation layer 40.

In some embodiments, each of the electrodes 30 and 32 includes one or more conformal conductive layers. In some embodiments, the electrodes 30 and 32 can include, for example but are not limited to, metals, alloys, doped semiconductor materials (such as doped crystalline silicon), other conductor materials, or combinations thereof. The exemplary materials of the electrodes 30 and 32 can include, for example but are not limited to, Ti, AlSi, TiN, or combinations thereof. In some embodiments, each of the electrodes 30 and 32 forms ohmic contact with the nitride-based semiconductor layer 16. The ohmic contact can be achieved by applying Ti,

Al, or other suitable materials for the electrodes 30 and 32.

The passivation layer 42 is disposed above the passivation layer 40 and the electrodes 30 and 32. The passivation layer 42 covers the GaN-based HEMT. The passivation layer 42 covers the electrodes 30 and 32. The passivation layer 42 may have a flat topmost surface, which is able to act as a flat base for carrying layers formed in a step subsequent to the formation thereof. The exemplary materials of the passivation layer 42 can include, for example but are not limited to, SiNx, SiOx, SiON, SiC, SiBN, SiCBN, oxides, nitrides, or combinations thereof. In some embodiments, the passivation layer 42 is a multi-layered structure, such as a composite dielectric layer of A1₂O₃/SiN, Al₂O₃/SiO₂, AlN/SiN, AlN/SiO₂, or combinations thereof.

The contact vias 50 penetrate the passivation layer 42 to connect to the gate electrode 22 and the electrodes 30 and 32. The contact vias 50 form interfaces with the gate electrode 22 and the electrodes 30 and 32. The exemplary materials of the contact vias 50 can include, for example but are not limited to, Cu, Al, or combinations thereof.

The patterned conductive layer 52 is disposed on the passivation layer 42. The patterned conductive layer 52 has a plurality of metal lines over the gate electrode 22 and the electrodes 30 and 32 for the purpose of implementing interconnects between circuits. The metal lines are in contact with the contact vias 50, respectively, such that gate electrode 22 and the electrodes 30 and 32 can be arranged into a circuit. For example, the GaN-based HEMT can be electrically connected to other component(s) via the metal lines of the patterned conductive layer 52. In other embodiments, the patterned conductive layer 52 may include pads or traces for the same purpose.

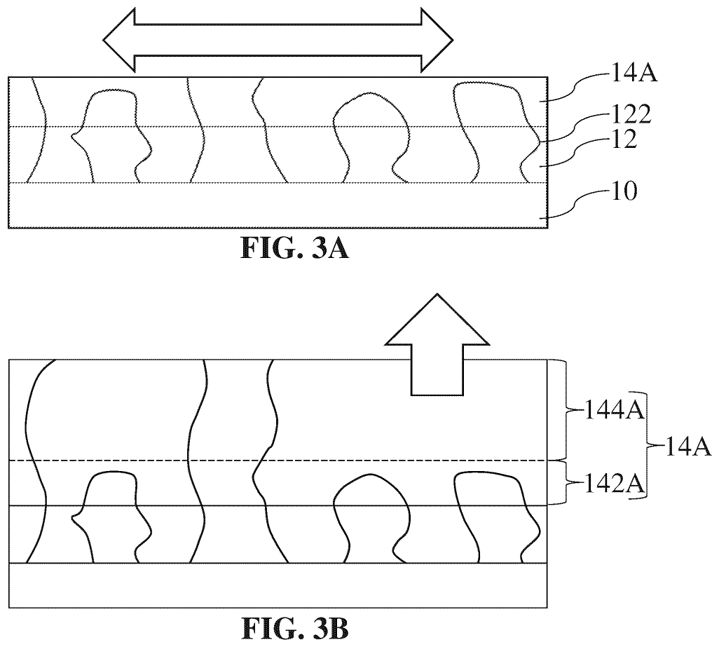

To run a method for manufacturing the semiconductor device 1A, receipts for the growth of the nitride-based semiconductor layer 14A can be turned. FIG. 3A and FIG. 3B show different stages of a method for manufacturing a nitride-based semiconductor device according to some embodiments of the present disclosure. In the following descriptions, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 3A, a buffer layer 12 is formed on a substrate 10, and a III-V nitride-based semiconductor layer 14A is formed on the buffer layer 12. During the growth of the buffer layer 12, dislocation lines 122 extend in the buffer layer 12. After the growth of the buffer layer 12, dislocation lines 122 pass through the buffer layer 12. The III-V nitride-based semiconductor layer 14A is formed by applying a low V/III ratio during the growth thereof. As afore-described, during the growth of the III-V nitride-based semiconductor layer 14A, lateral growth energy is greater than longitudinal growth energy so some of dislocation lines in the III-V nitride-based semiconductor layer 14A extend laterally.

Referring to FIG. 3B, the III-V nitride-based semiconductor layer 14A continues to grow so a top portion 144A is formed on a bottom portion 142A. The top portion 144A of the III-V nitride-based semiconductor layer 14A is formed by applying a high V/III ratio during the growth thereof. As afore-described, during the growth of the top portion 144A of the III-V nitride-based semiconductor layer 14A, longitudinal growth energy is greater than lateral growth energy so dislocation lines in the top portion 144A of the extend longitudinally.

After the formation of the III-V nitride-based semiconductor layer 14A, a III-V nitride-based semiconductor layer for serving as a barrier layer can be formed on the III-V nitride-based semiconductor layer 14A. Thereafter, a nitride-based transistor as afore-described can be formed in the barrier layer so as to obtain the semiconductor device of FIG. 1.

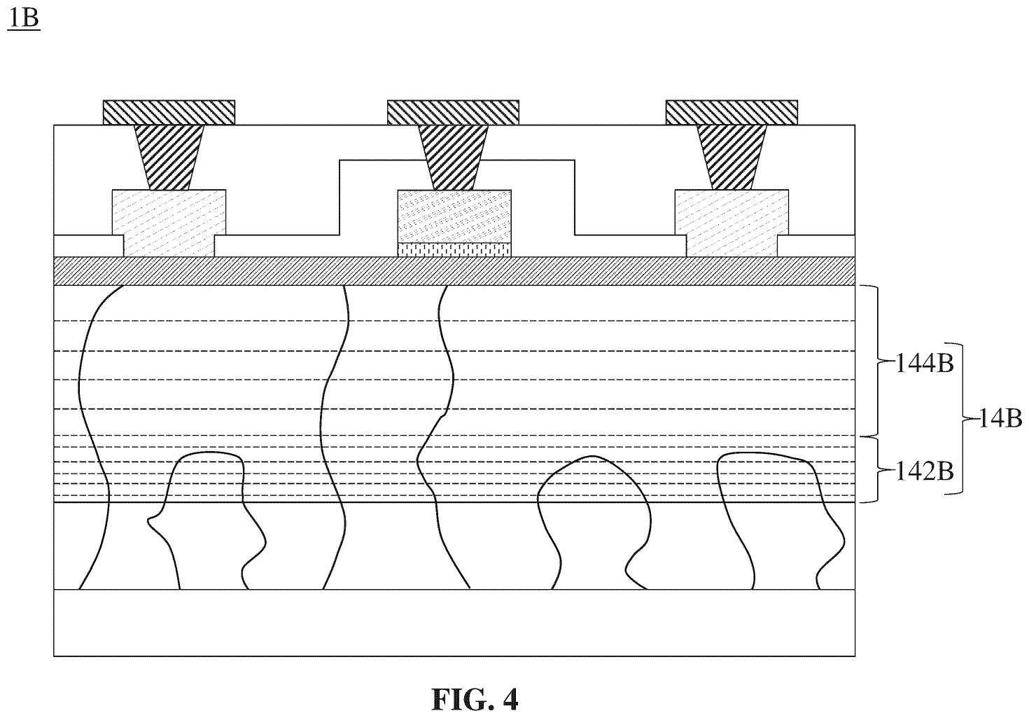

FIG. 4 is a vertical cross-sectional view of a semiconductor device 1B according to some embodiments of the present disclosure. The semiconductor device 1B is similar to the semiconductor device 1A as described and illustrated with reference to FIG. 1A, except that the III-V nitride-based semiconductor layer 14A of FIG. 1A is replaced by a III-V nitride-based semiconductor layer 14B.

In the present embodiment, the V/III ratio of the III-V nitride-based semiconductor layer 14B from the bottom portion 142B to the top portion 144B is stepwise increasing.

At the bottom portion 142B, multiple dashed lines are illustrated, which represent boundaries of sub-layers have different V/III ratios. Herein, the phrase “stepwise increasing” means two adjacent sub-layers have a gap in their V/III ratios so the V/III ratios are not continuous. For example, the first one of the sub-layers may have a V/III ratio at about 50 or in a range between 45 to 55; and the second one of the sub-layers may have a V/III ratio at about 70 or in a range between 65 to 75. In some embodiments, two adjacent sub-layers of the bottom portion 142B have different V/III ratios which are non-overlapped with each other (i.e., the value ranges are not overlapped).

At the top portion 144B, multiple dashed lines are illustrated, which represent boundaries of sub-layers have different V/III ratios. Similarly to the bottom portion 142B, any two of adjacent sub-layers of the top portion 144B have a gap in their V/III ratios so the V/III ratios are not continuous. In some embodiments, each of the sub-layers of the bottom portion 142B is thinner than each of the sub-layers of the top portion 144B. The reason is the sub-layers of the bottom portion 142B are made to turn dislocation lines therein so meticulous increasing the VIII ratio may be required. At the top portion 144B, since the profile of the dislocate lines are almost fixed so each of the sub-layers of the top portion 144B can be flexible.

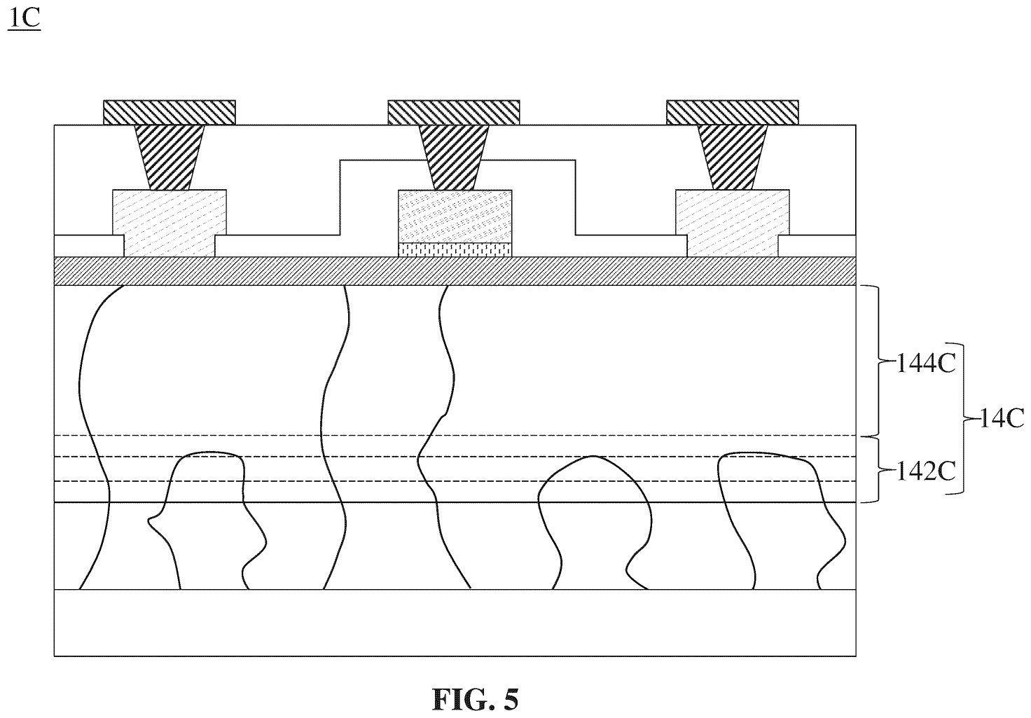

FIG. 5 is a vertical cross-sectional view of a semiconductor device 1C according to some embodiments of the present disclosure. The semiconductor device 1C is similar to the semiconductor device 1A as described and illustrated with reference to FIG. 1A, except that the III-V nitride-based semiconductor layer 14A of FIG. 1A is replaced by a III-V nitride-based semiconductor layer 14C.

In the present embodiment, the V/III ratio of the III-V nitride-based semiconductor layer 14C within the bottom portion 142C is stepwise increasing; and the V/III ratio of the III-V nitride-based semiconductor layer 14C within the top portion 144C is gradually increasing.

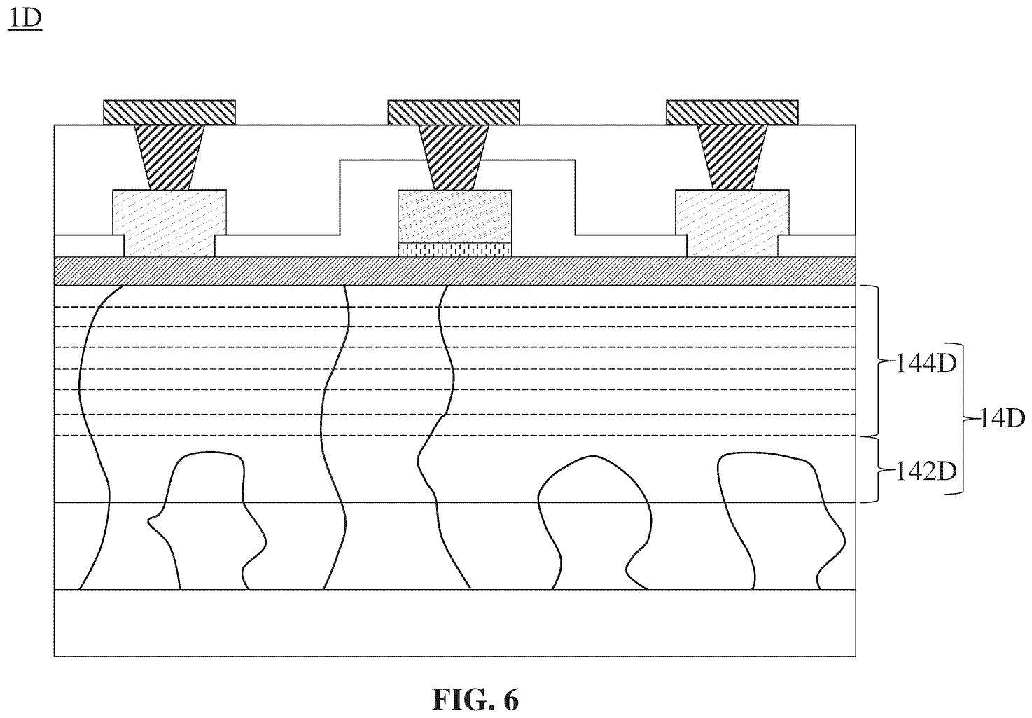

FIG. 6 is a vertical cross-sectional view of a semiconductor device 1D according to some embodiments of the present disclosure. The semiconductor device 1D is similar to the semiconductor device 1A as described and illustrated with reference to FIG. 1A, except that the III-V nitride-based semiconductor layer 14A of FIG. 1A is replaced by a III-V nitride-based semiconductor layer 14D.

In the present embodiment, the V/III ratio of the III-V nitride-based semiconductor layer 14D within the bottom portion 142D is gradually increasing; and the V/III ratio of the III-V nitride-based semiconductor layer 14D within the top portion 144D is stepwise increasing.

Since the epitaxial growth requires highly requirement on process conditions, flexible process recipes serve as important factors for the manufacturing process. Adjusting the gradient of V/III ration is flexible. It can be achieved by gradually or stepwise varying.

By the above configuration, the III-V nitride-based semiconductor layer can be formed with the sub-III-V nitride-based layers with different V/III ratios. The different V/III ratios can let dislocation line turn to extend laterally, so the dislocation line can become reverse U-shaped so to reduce dislocation density.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

To the claims:

1. A nitride-based semiconductor device comprising:
a III-V nitride-based buffer layer disposed over a substrate to form a first interface with the substrate, wherein the III-V nitride-based buffer layer has a plurality of first dislocation lines extending from the first interface to a top surface of the III-V nitride-based buffer layer;
a first III-V nitride-based semiconductor layer disposed over the III-V nitride-based buffer layer to form a second interface with the top surface of the III-V nitride-based buffer layer, wherein the first III-V nitride-based semiconductor layer has a plurality of second dislocation lines and third dislocation lines, each of the second dislocation lines connects two of the first dislocation lines, and each of the third dislocation lines continuously extends from corresponding one of the first dislocation lines to a top surface of the first III-V nitride-based semiconductor layer; and
a second III-V nitride-based semiconductor layer disposed over the first III-V nitride-based semiconductor layer to form a third interface with the top surface of the first III-V nitride-based semiconductor layer.

2. The nitride-based semiconductor device of claim 1, wherein a bottom portion and a top portion of the first III-V nitride-based semiconductor layer have different concentrations of a group III element than each other.

3. The nitride-based semiconductor device of claim 2, wherein the bottom portion and the top portion of the first III-V nitride-based semiconductor layer have different V/III ratios resulting in the different concentrations thereof.

4. The nitride-based semiconductor device of claim 3, wherein the V/III ratio of the bottom portion is lower than the V/III ratio of the top portion.

5. The nitride-based semiconductor device of claim 3, wherein the V/III ratio of the first III-V nitride-based semiconductor layer from the bottom portion to the top portion is gradually increasing.

6. The nitride-based semiconductor device of claim 3, wherein the V/III ratio of the first III-V nitride-based semiconductor layer from the bottom portion to the top portion is stepwise increasing.

7. The nitride-based semiconductor device of claim 3, wherein the V/III ratio of the first III-V nitride-based semiconductor layer from the bottom portion to the top portion is in a range from about 200 to about 500.

8. The nitride-based semiconductor device of claim 2, wherein a dislocation density of the bottom portion is greater than a dislocation density of the top portion.

9. The nitride-based semiconductor device of claim 1, wherein each of the second dislocation lines turns around in the first III-V nitride-based semiconductor layer.

10. The nitride-based semiconductor device claim 1, wherein each of the second dislocation lines is reverse U-shaped.

11. The nitride-based semiconductor device of claim 1, wherein each of the second dislocation lines is more curved than the first and third dislocation lines.

12. The nitride-based semiconductor device of claim 1, wherein none of the second dislocation lines penetrates the first III-V nitride-based semiconductor layer.

13. The nitride-based semiconductor device of claim 1, further comprising:
a third nitride-based semiconductor layer disposed on the second nitride-based semiconductor layer and having a bandgap greater than a bandgap of the second nitride-based semiconductor layer, so as to form a heterojunction therebetween with a two-dimensional electron gas (2DEG) region; and
a nitride-based transistor disposed over the third nitride-based semiconductor layer and applying the 2DEG region as a channel.

14. The nitride-based semiconductor device of claim 1, wherein the III-V nitride-based buffer layer comprises aluminum nitride (AlN).

15. The nitride-based semiconductor device of claim 1, wherein the first III-V nitride-based semiconductor layer comprises gallium nitride (GaN), aluminum gallium nitride (AlGaN), or combinations thereof.

16. A method for manufacturing a nitride-based semiconductor device, comprising:
forming a III-V nitride-based buffer layer over a substrate with a plurality of first dislocation lines extending in the III-V nitride-based buffer layer;
forming a first III-V nitride-based semiconductor layer over the III-V nitride-based buffer layer by applying a first V/III ratio during growth of the first III-V nitride-based semiconductor layer, such that a plurality of second dislocation lines are formed in the first III-V nitride-based semiconductor layer with each of the second dislocation lines connected two of the first dislocation lines; and
forming a second III-V nitride-based semiconductor layer over the first III-V nitride-based semiconductor layer by applying a second V/III ratio during growth of the second III-V nitride-based semiconductor layer, wherein the first V/III ratio is lower than the second V/III ratio.

17. The method of claim 16, the first V/III ratio is equal to or less than about 200.

18. The method of claim 16, the second V/III ratio is equal to or greater than about 500.

19. The method of claim 16, wherein the III-V nitride-based buffer layer comprises aluminum nitride (AlN).

20. The method of claim 16, wherein the first III-V nitride-based semiconductor layer comprises gallium nitride (GaN), aluminum gallium nitride (AlGaN), or combinations thereof.

21-25. (canceled)
